(19) United States
(12) Patent Application Publication
(10) Pub. No.: US 2025/0138414 A1
(43) Pub. Date: May 1, 2025

(54) STAMP FOR IMPRINT LITHOGRAPHY

(71) Applicant: DISPELIX OY, Espoo (FI)

(72) Inventor: Anni ERONEN, Joensuu (FI)

(73) Assignee: DISPELIX OY, Espoo (FI)

(21) Appl. No.: 18/837,830

(22) PCT Filed: Jan. 31, 2023
(86) PCT No.: PCT/FI2023/050062

§ 371 Date: Aug. 12, 2024

(30) Foreign Application Priority Data
Feb. 22, 2022 (FI) 20225159

(51) Int. Cl. G03F 7/00

(52) U.S. Cl. CPC G03F 7/0002

(57) ABSTRACT

According to an embodiment, a stamp for imprint lithography defines a desired shape for a curable resin, wherein the stamp is at least partially transparent to electromagnetic radiation used to cure the curable resin, and wherein the stamp comprises at least one diffuser structure for diffusing the electromagnetic radiation as the electromagnetic radiation propagates through the stamp.

### TECHNICAL FIELD

The present disclosure relates to the field of imprint lithography, and more particularly to a stamp for imprint lithography, a method for imprint lithography, and an arrangement for imprint lithography.

### BACKGROUND

In imprint lithography, any obstacle between a light source and a curable resin or any nonuniformity in the light source can cause uneven dose in different regions of the resin. This can lead to situations where uncured and cured areas can be present. Increasing the total dose, by for example increasing the exposure time or the light source power, can mitigate the issue to some extent but can also cause overcuring, which can manifest as cracking of the resin or other type of harm to the resin.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an object to provide a stamp for imprint lithography, a method for imprint lithography, and an arrangement for imprint lithography. The foregoing and other objects are achieved by the features of the independent claims. Further implementation forms are apparent from the dependent claims, the description and the figures.

According to a first aspect, a stamp for imprint lithography defines a desired shape for a curable resin, wherein the stamp is at least partially transparent to electromagnetic radiation used to cure the curable resin, and wherein the stamp comprises at least one diffuser structure for diffusing the electromagnetic radiation as the electromagnetic radiation propagates through the stamp.

According to second aspect, a method for imprint lithography comprises: providing a wafer with a curable resin on the wafer, wherein the curable resin is curable using electromagnetic radiation; providing a stamp according the first aspect; transferring the desired shape from the stamp onto the curable resin by pressing the stamp onto the resin; and curing the resin by emitting electromagnetic radiation onto the resin through the stamp.

According to a third aspect, an arrangement for imprint lithography comprises: a structure for holding a wafer with a curable resin on the wafer, wherein the curable resin is curable using electromagnetic radiation; a stamp according to the first aspect for transferring the desired shape from the stamp onto the curable resin when the stamp is pressed onto the resin; and an electromagnetic radiation source for curing the resin by emitting the electromagnetic radiation onto the resin through the stamp when the stamp is pressed onto the resin.

Many of the attendant features will be more readily appreciated as they become better understood by reference to the following detailed description considered in connection with the accompanying drawings.

### DESCRIPTION OF THE DRAWINGS

In the following, example embodiments are described in more detail with reference to the attached figures and drawings, in which:

FIG. 1 illustrates a schematic representation of a stamp for imprint lithography;

FIG. 2 illustrates a flow chart representation of a method for imprint lithography; and

FIG. 3 illustrates a schematic representation of an arrangement for imprint lithography.

In the following, identical reference signs refer to similar or at least functionally equivalent features.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilised, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

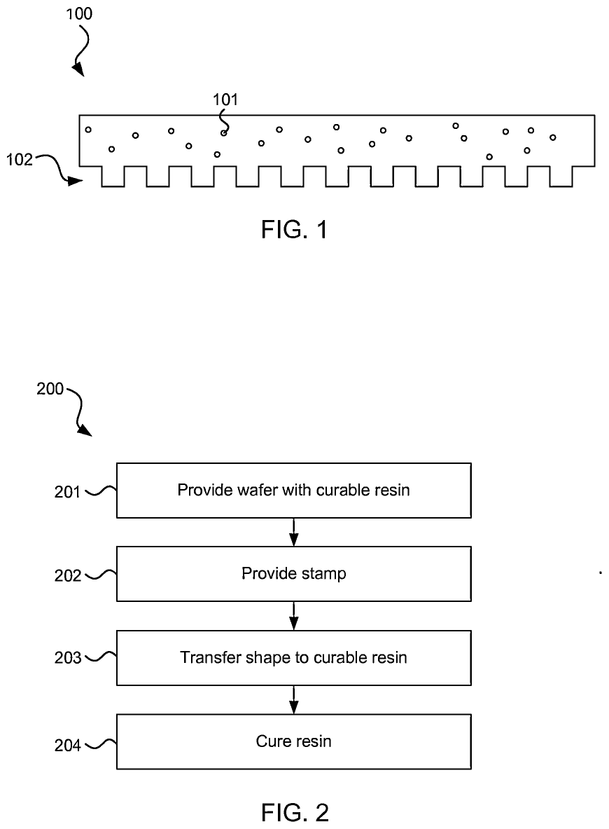

FIG. 1 illustrates a schematic representation of a stamp for imprint lithography.

According to an embodiment, the stamp 100 defines a desired shaped for a curable resin, the stamp is at least partially transparent to electromagnetic radiation used to cure the curable resin, and the stamp comprises at least one diffuser structure 101 for diffusing the electromagnetic radiation as the electromagnetic radiation propagates through the stamp.

The stamp 100 can define the desired shape via a pattern 102 on one side of the stamp 100. Thus, when the stamp 100 is pressed onto the resin, the desired shape is transferred to the resin as the pattern 102 on the stamp 100 deforms the surface of the resin. For example, in the embodiment of FIG. 1, the pattern 102 of the stamp 100 comprises protrusions defining the desired shape. It should be appreciated that the onedimensional pattern 102 illustrated in the embodiment of FIG. 1 is only a simplified example for illustrative purposes.

Herein, imprint lithography may comprise, for example, nanoimprint lithography (NIL), photo nanoimprint lithography (P-NIL), ultraviolet nanoimprint lithography (UV-NIL), or any other type of imprint lithography.

The stamp 100 can reduce uneven curing of the curable resin, since the stamp can diffuse the electromagnetic radiation and thus spatially even the curing of the resin. Thus, the stamp itself can function as a diffuser that causes the radiation to spread more evenly 20 on the resin. Since there is nothing between stamp 100 and resin when the stamp 100 is placed onto the resin, most of the diffused light ends up going into the resin. Thus, losses can also be reduced. Moreover, a separate diffuser or a diffuser in the electromagnetic radiation source may not be needed.

The stamp 100 may also be referred to as a stamper, a mould, or similar.

According to an embodiment, the at least one diffuser structure 101 comprises microparticles and/or nanoparticles.

For example, in the embodiment of FIG. 1, the stamp 100 comprises particles, such as microparticles and/or nanoparticles, as the diffuser structure 101.

According to an embodiment the stamp 100 comprises 0.1-5 weight percentage of the microparticles and/or nanoparticles.

Alternatively or additionally, the stamp 100 may comprise, for example, 0.2-4, 0.2-3, 0.2-2, 0.2-1, 0.3-1, and/or 0.4-0.6 weight percentage of the microparticles and/or nanoparticles.

According to an embodiment, the microparticles and/or nanoparticles comprise oxide, dioxide, silicon dioxide (SiO₂), titanium dioxide (TiO₂), zirconium dioxide (ZrO₂), hafnium dioxide (HfO₂), aluminium oxide (Al₂O₃), and/or indium tin oxide (ITO).

For example, the microparticles and/or nanoparticles may be made of oxide, dioxide, silicon dioxide, titanium dioxide, zirconium dioxide, hafnium dioxide, aluminium oxide, and/or indium tin oxide.

According to an embodiment, dimensions of the microparticles and/or nanoparticles are in the range 500 nanometres (nm)-900 micrometres (μm).

Alternatively or additionally, dimensions of the microparticles and/or nanoparticles can be in the range 500 nm-900 um, 500 nm-1000 nm, 5 μm-700 μm, 1 μm-900 μm, 10 μm-500 μm, 10 μm-200 μm, 50 μm-200 μm, and/or 50 μm-150 μm.

In some embodiments, the microparticles and/or nanoparticles may be microspheres and/or nanospheres. Diameters of the microspheres and/or nanospheres may be in the range 500 nanometres-900 micrometres. Alternatively or additionally, diameters of the microspheres and/or nanospheres can be in the range 500 nm-900 um, 500 nm-1000 nm, 5 μm-700 μm, 1 μm-900 μm, 10 μm-500 μm, 10 μm-200 μm, 50 μm-200 μm, and/or 50 μm-150 um.

According to an embodiment, the microparticles and/or nanoparticles comprise at least one of: micro-spheres and/or nanospheres, microrods and/or nanorods, microcubes and/or nanocubes, core-shell particles, nanopowder particles, raspberry-like particles, and/or spike particles.

Raspberry-like particles may refer to particles that comprise substantially spherical protrusions of the surface of the particle.

Nanopowders can be defined as powdered materials with individual particles in nanometre scale or materials with crystalline in nanometre scale.

In some embodiments, the particles may comprise clusters of various shapes, such as rods and/or spikes.

In some embodiments, the microparticles and/or nanoparticles can have random shapes.

In some embodiments, microparticles and/or nanoparticles can comprise oxide multi-layer particles, such as SiO₂/TiO₂ core-shell particles. Oxide multilayer particles can comprise a plurality of layers, wherein each layer comprises an oxide that can be different from the other layer. When a particle comprises two layers, this may be referred to as a core-shell particle.

The at least one diffuser structure 101 may also comprise any other type of structure for diffusing the electromagnetic radiation. For example, the at least one diffuser structure 101 may comprise a layer of diffusing material for diffusing the electromagnetic radiation, a region for diffusing the electromagnetic radiation, and/or a glass/plastic for diffusing the electromagnetic radiation. In some embodiments, the stamp 100 may be made of a glass/plastic that is configured to diffuse the electromagnetic radiation.

According to an embodiment, the stamp comprises a polymer, polydimethylsiloxane (PDMS), epoxy, silicone, and/or an inorganic-organic hybrid polymer stamp.

For example, the stamp may be made of a polymer, polydimethylsiloxane, epoxy, silicone, and/or an inorganic-organic hybrid polymer stamp.

The stamp 100 can comprise, for example, different sized and shaped silica or any other dioxide nano- and/or microparticles. Also different concentrations of nano/microparticles can be used.

The stamp 100 can be manufactured by, for example, adding the diffusing material, such as micro and/or nanoparticles into a liquid material and casting the liquid material into the desired shape. The material can comprise, for example, any polymer-based material that is in liquid form before casting.

FIG. 2 illustrates a flow chart representation of a method for imprint lithography. According to an embodiment, the method 200 comprises providing 201 a wafer with a curable resin on the wafer, wherein the curable resin is curable using electromagnetic radiation.

The method 200 may further comprise providing 202 a stamp 100.

The method 200 may further comprise transferring 203 the desired shape from the stamp onto the curable resin by pressing the stamp onto the resin.

The method 200 may further comprise curing 204 the resin by emitting electromagnetic radiation onto the resin through the stamp.

The method 200 may further comprise removing the stamp from the curable resin.

The method 200 may further comprise transferring the pattern from the cured resin to the wafer using a pattern transfer process, such as reactive ion etching or some other etching process.

According to an embodiment, the resin is ultraviolet curable, and the electromagnetic radiation comprises ultraviolet light.

Alternatively, the curable resin may be curable by some other type of light, such as visible light or infrared light, and the electromagnetic radiation may comprise that type of light.

According to an embodiment, dimensions of the microparticles and/or nanoparticles in the stamp are greater than a wavelength of the electromagnetic radiation.

Depending on the wavelength of the electromagnetic radiation, the size of the micro-and/or nanoparticles may need to be configured accordingly. Furthermore, the appropriate weight percentage of the micro- and/or nanoparticles in the stamp may also depend on the wavelength of the electromagnetic radiation.

According to an embodiment, the desired shape comprises a lattice structure for an optical diffraction grating.

Alternatively or additionally, the desired shape may comprise the shape of any other component, such as an optical component, a diffractive optical element, a microlens array, a waveguide, a wafer optics component, a diffuser, and/or a nano/microstructure.

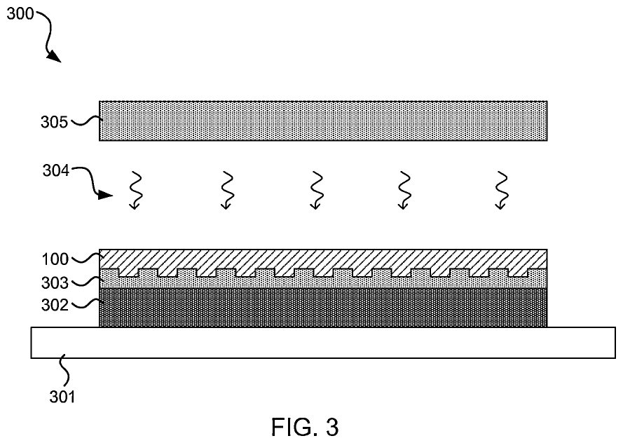

FIG. 3 illustrates a schematic representation of an arrangement for imprint lithography.

According to an embodiment, the arrangement 300 comprises a structure 301 for holding a wafer 302 with a curable resin 303 on the wafer 302, wherein the curable resin 303 is curable using electromagnetic radiation 304.

The wafer 302 may also be referred to as a substrate or similar.

The arrangement 300 may further comprise a stamp 100 for transferring the desired shape from the stamp 100 onto the curable resin 303 when the stamp 100 is pressed onto the resin 303.

The arrangement 300 may further comprise an electromagnetic radiation source 305 for curing the resin 303 by emitting the electromagnetic radiation 304 onto the resin 303 through the stamp 100 when the stamp 100 is pressed onto the resin 303.

After the stamp 100 has been pressed onto the curable resin 303 and the resin 303 has been cured, the stamp 100 can be removed. Thus, the pattern is transferred to the cured resin 303. A pattern transfer process, such as reactive ion etching or some other etching process, can be used to transfer the pattern from the resin 303 to the wafer 302.

The arrangement 300 may further comprise other components/structures. For example, the arrangement 300 may comprise components for pressing the stamp 100 onto the curable resin 303 and/or for removing the stamp 100 from the curable resin 303.

According to an embodiment, the arrangement 300 further comprises a pressing device for pressing the stamp 100 onto the resin 303.

According to an embodiment, the arrangement 300 further comprises a removal device for removing the stamp 100 from the resin 303 after the resin 303 has cured.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. A stamp for imprint lithography, the stamp defining a desired shape for a curable resin, wherein the stamp is at least partially transparent to electromagnetic radiation used to cure the curable resin, and wherein the stamp comprises at least one diffuser structure for diffusing the electromagnetic radiation as the electromagnetic radiation propagates through the stamp, wherein the stamp comprises microparticles and/or nanoparticles as the at least one diffuser structure.

2. The stamp according to claim 1, wherein the stamp comprises 0.1-5 weight percentage of the microparticles and/or nanoparticles.

3. The stamp according to claim 1, wherein the microparticles and/or nanoparticles comprise oxide, dioxide, silicon dioxide, titanium dioxide, zirconium dioxide, hafnium dioxide, aluminium oxide, and/or indium tin oxide.

4. The stamp according to claim 1, wherein dimensions of the microparticles and/or nanoparticles are in the range 500 nanometres-900 micrometres.

5. The stamp according to claim 1, wherein the microparticles and/or nanoparticles comprise at least one of:
microspheres and/or nanospheres;
microrods and/or nanorods;
microcubes and/or nanocubes;
core-shell particles;
nanopowder particles;
raspberry-like particles; and/or
spike particles.

6. The stamp according to claim 1, wherein the stamp comprises a polymer, polydimethylsiloxane, epoxy, silicone, and/or an inorganic-organic hybrid polymer stamp.

7. A method for imprint lithography, the method comprising:
providing a wafer with a curable resin on the wafer, wherein the curable resin is curable using electromagnetic radiation;
providing a stamp according to claim 1;
transferring the desired shape from the stamp onto the curable resin by pressing the stamp onto the resin; and
curing the resin by emitting electromagnetic radiation onto the resin through the stamp.

8. The method according to claim 7, wherein the resin is ultraviolet curable, and the electromagnetic radiation comprises ultraviolet light.

9. The method according to claim 7, wherein dimensions of the microparticles and/or nanoparticles in the stamp are greater than a wavelength of the electromagnetic radiation.

10. The method according to claim 1, wherein the desired shape comprises a lattice structure for an optical diffraction grating.

11. An arrangement for imprint lithography, the arrangement comprising:
a structure for holding a wafer with a curable resin on the wafer, wherein the curable resin is curable using electromagnetic radiation;
a stamp according to claim 1 for transferring the desired shape from the stamp onto the curable resin when the stamp is pressed onto the resin; and
an electromagnetic radiation source for curing the resin by emitting the electro-magnetic radiation onto the resin through the stamp when the stamp is pressed onto the resin.

12. The arrangement according to claim 11 further comprising a pressing device for pressing the stamp onto the resin.

13. The arrangement according to claim 12 further comprising a removal device for removing the stamp from the resin after the resin has cured.
